(19) United States
(12) Patent Application Publication
(10) Pub. No.: US 2025/0038157 A1
(43) Pub. Date: Jan. 30, 2025

(54) POWER SUPPLY MODULE

(71) Applicant: Murata Manufacturing Co., Ltd., Nagaokakyo-shi, Kyoto-fu (JP)

(72) Inventors: Takami MUTO, San Jose, CA (US); Hiroki MINAMI, Nagaokakyo-shi (JP); Munetake MIYASHITA, Nagaokakyo-shi (JP); Masanari TAGO, San Jose, CA (US)

(21) Appl. No.: 18/716,188

(22) PCT Filed: Feb. 17, 2023
(86) PCT No.: PCT/US2023/013343

§ 371 Date: Jun. 4, 2024

Related U.S. Application Data
(60) Provisional application No. 63/311,746, filed on Feb. 18, 2022.

(51) Int. Cl. H01L 25/16; H01L 23/31; H01L 23/367; H01L 23/538

(52) U.S. Cl. CPC H01L 25/162; H01L 23/3675; H01L 23/5385; H01L 23/3107; H01L 28/10; H01L 28/20; H01L 28/40

(57) ABSTRACT

A power supply module includes a first substrate; a control IC, a capacitor, a first electronic component, a second electronic component, a third electronic component and a fourth electronic component on a principal surface of the first substrate; a first submodule including a second substrate above the first electronic component, the second electronic component, the third electronic component, and the fourth electronic component and including a fifth electronic component, a sixth electronic component, and a seventh electronic component on a principal surface of the second substrate; and a resin covering an upper portion of the first submodule.

### CROSS REFERENCE TO RELATED APPLICATIONS

This application claims the benefit of U.S. Patent Application No. 63/311,746 filed on Feb. 18, 2022. The entire contents of this application are hereby incorporated by reference.

### BACKGROUND OF THE INVENTION

### 1. Field of the Invention

The present invention relates to power supply modules including substrates upon which electronic components are mounted to provide prescribed functions.

### 2. Description of the Related Art

Known power supply modules include electronic components disposed on substrates. For example, Japanese Unexamined Patent Application Publication No. 2011-114259 discloses such a known power supply module.

With the recent miniaturization and multifunctionality of servers and other equipment, there is a growing demand for miniaturization and high integration of modules that provide a large number of functions by integrating multiple electronic components. To meet this demand, Japanese Unexamined Patent Application Publication No. 2011-114259, for example, discloses a power supply module in which a number of electronic components are arranged on a single substrate and packaged as a single module. In the power supply module described in Japanese Unexamined Patent Application Publication No. 2011-114259, an additional substrate is placed above a common substrate on which electronic components are mounted, and additional electronic components are also mounted on the additional substrate.

However, in the power supply module of Japanese Unexamined Patent Application Publication No. 2011-114259, if the power supply module is to be highly integrated by mounting additional electronic components on another substrate provided above the common substrate, then it is necessary to increase the area of this upper substrate. And as the area of this upper substrate increases, the strength of the upper substrate can become an issue. That is, as more electronic components are added the power supply module, the upper substrate cannot bear the weight of the additional components so that the upper substrate deforms or warps. As a result, problems such as poor electrical connections can occur between electronic components mounted on the upper substrate or between the electronic components on the common substrate.

### SUMMARY OF THE INVENTION

To overcome the problems described above, preferred embodiments of the present invention provide power supply modules that allow more electronic components to be mounted and that allow more flexibility in design of functions, size, performance, etc., according to application and performance requirements.

More specifically, by using a plurality of second substrates or submodules located in a direction perpendicular or substantially perpendicular within manufacturing and/or measurement tolerances to a principal surface of a first substrate, various electronic components can be located not only on a principal surface of the first substrate but also on these second substrates or submodules, which allows more electronic components to be used than if only the first substrate were included.

Moreover, by using a plurality of second substrates or submodules, adjustments, such as reducing the area of each of the second substrates or submodules, can be made. As a result, it becomes possible to ensure adequate strength of these second substrates or submodules. The number, shape, and size of the various electronic components located on the power supply module can also be changed according to the shape and size of the first substrate and of the second substrates or submodules. The number and the type of electronic components included on the second substrate or submodules can be changed. Thus, power supply modules with various functions can be provided.

A plurality of submodules can be located on the principal surface of the first substrate. For example, increasing the number of submodules can increase achievable power output. When more than one submodule is used, the submodules can be electrically connected to each other.

According to a preferred embodiment of the present invention, a power supply module includes a first substrate; a control IC, a capacitor, a first electronic component, a second electronic component, a third electronic component and a fourth electronic component on a principal surface of the first substrate on a principal surface of the first substrate; and a submodule including a second substrate above the first electronic component, the second electronic component, the third electronic component, and the fourth electronic component, including a fifth electronic component, a sixth electronic component, and a seventh electronic component on a principal surface of the second substrate, and including a resin covering an upper portion of the first submodule.

The first electronic component can be an inductor. The second electronic component can be a ground terminal. The third electronic component can be a voltage input terminal. The fourth electronic component can be a signal transmission substrate. The fifth electronic component can be a power element. The module can further include a heat sink above the power element. The sixth electronic component can be a capacitor. The seventh electronic component can be a resistor. The module can further include one or more additional submodules, and the submodule and the one or more additional submodules can be electrically connected to each other.

According to a preferred embodiment of the present invention, a power supply module includes a first substrate; a control IC, a capacitor, a first electronic component, a second electronic component, a third electronic component, and a fourth electronic component on a principal surface of the first substrate; a submodule including a second substrate above the first electronic component, the second electronic component, the third electronic component, and the fourth electronic component, including a fifth electronic component, a sixth electronic component, and a seventh electronic component on a principal surface of the second substrate, and including a resin covering an upper portion of the first submodule; and a metal plate on a principal surface of the first substrate where the first submodule is not located.

The first electronic component can be an inductor. The second electronic component can be a ground terminal. The third electronic component can be a voltage input terminal. The fourth electronic component can be a signal transmission substrate. The fifth electronic component can be a power element. The module can further include a heat sink above the power element. The sixth electronic component can be a capacitor. The seventh electronic component can be a resistor. The module can further include one or more additional submodules, and the submodule and the one or more additional submodules can be electrically connected to each other.

According to a preferred embodiment of the present invention, a power supply module includes a first substrate; first and second submodules, each of the first and second submodules includes a second substrate, a signal transmission substrate connected between the first substrate and the second substrate, a power element on a first principal surface of the second substrate opposite to the first substrate, and an inductor on a second principal surface of the second substrate facing the first substrate and electrically connected with the power element.

The module can further include a metal plate on a principal surface of the first substrate where the first and second submodules are not located.

The module can further include third and fourth submodules, the first and the second submodules are arranged in a first line, and wherein the third and the fourth submodules are arranged in a second line adjacent to the first line. The module can further include a control IC on the first substrate.

The module can further include first and second electronic components mounted to the first substrate, wherein the first electronic component can be underneath a portion of the inductor of the first submodule and wherein the second electronic components can be underneath a portion of the second submodule.

Each of the first and the second submodules can include a resin covering an upper portion of thereof.

Each of the first and the second submodules can include first and second voltage input terminals, the first voltage input terminal can be connected between the first substrate and a first end of the second substrate, and the second voltage input terminal can be connected between the first substrate and a second end of the second substrate opposite to the first end of the second substrate.

Each of the first and the second submodules can include first and second ground terminals, the first ground terminal can be connected between the first substrate and the first end of the second substrate, the second ground terminal can be connected between the first substrate and the second end of the second substrate, and the first and the second ground terminals can be located inside the first and the second voltage input terminals.

Each of the first and the second submodules can include a heat sink above the power element. The first and the second submodules can be electrically connected.

The above and other features, elements, characteristics, steps, and advantages of the present invention will become more apparent from the following detailed description of preferred embodiments of the present invention with reference to the attached drawings.

### BRIEF DESCRIPTION OF THE DRAWINGS

FIG. 1 shows a perspective view of a power supply module according to a first preferred embodiment of the present invention.

FIG. 2 shows a cross-sectional block diagram of the power supply module of FIG. 1 with the resin molding removed.

FIG. 3 shows a top view of the power supply module of FIG. 1.

FIG. 4A shows a front view of a submodule mounted on the power supply module of FIG. 1.

FIG. 4B shows a rear view of the submodule mounted on the power supply module of FIG. 1.

FIG. 5A shows a top view of the submodule mounted on the power supply module of FIG. 1 with the resin molding and the heat sink removed.

FIG. 5B shows a bottom view of the submodule mounted on the power supply module of FIG. 1.

FIG. 6 shows a circuit diagram of the submodule mounted on the power supply module 1 of FIG. 1.

FIG. 7 shows a perspective view of a power supply module according to a second preferred embodiment of the present invention.

FIG. 8 shows a cross-sectional block diagram of the power supply module of FIG. 7.

FIG. 9 shows a top view of the power supply module of FIG. 7.

FIG. 10 shows a top view of the power supply module of FIG. 7 with the metal plate molding removed.

FIG. 11A shows a front view of a submodule mounted on the power supply module of FIG. 7.

FIG. 11B shows a rear view of the submodule mounted on the power supply module of FIG. 7.

FIG. 12A shows a top view of the submodule mounted on the power supply module of FIG. 7 with the resin molding and the heat sink removed.

FIG. 12B shows a bottom view of the submodule mounted on the power supply module of FIG. 7.

FIG. 13 shows a circuit diagram of the submodule mounted on the power supply module of FIG. 7.

### DETAILED DESCRIPTION OF PREFERRED EMBODIMENTS

Power supply modules according to the preferred embodiments of the present invention are described below with reference to the drawings. It should be noted that all of the following examples show a preferred embodiment of the present invention. The numerical values, shapes, materials, components, locations, positions of components and connection modes shown in the following examples are examples and are not intended to limit the present invention. Also, the size or ratio of sizes of the components shown in the drawings is not always exact.

### First Preferred Embodiment

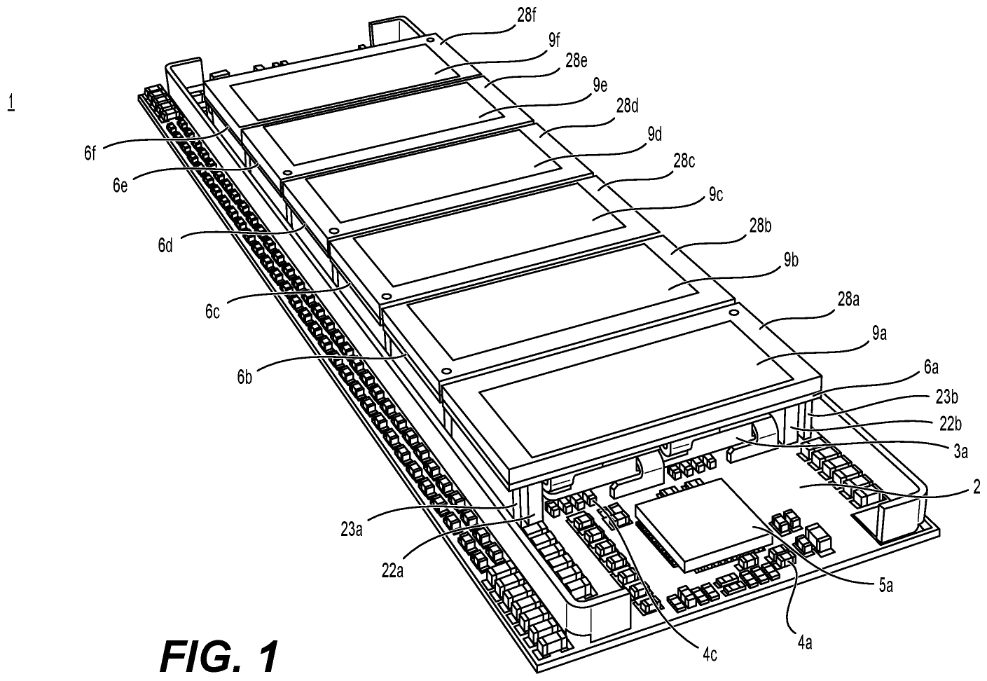

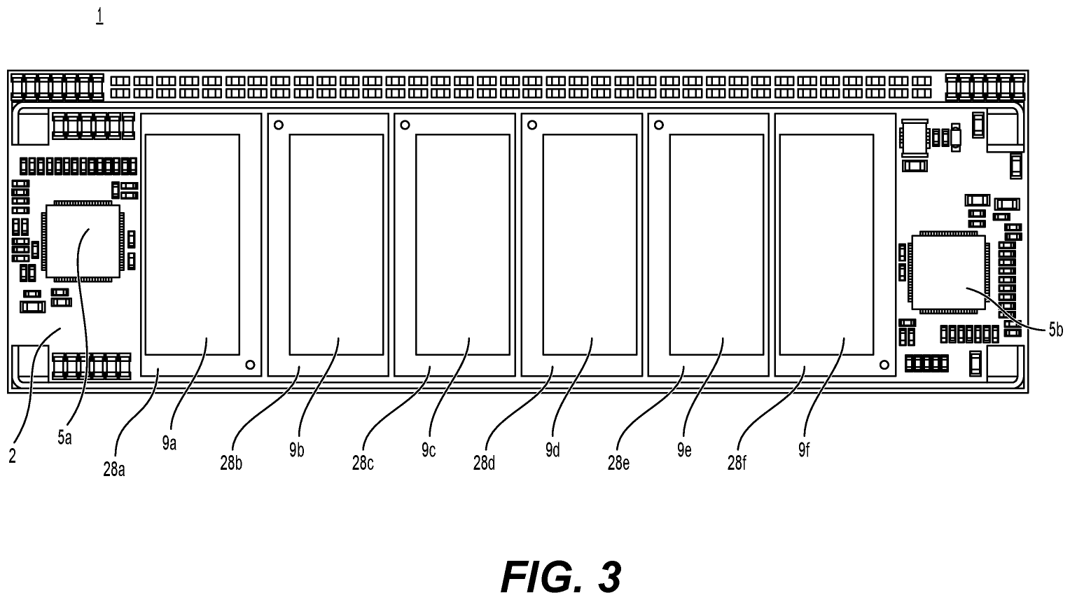

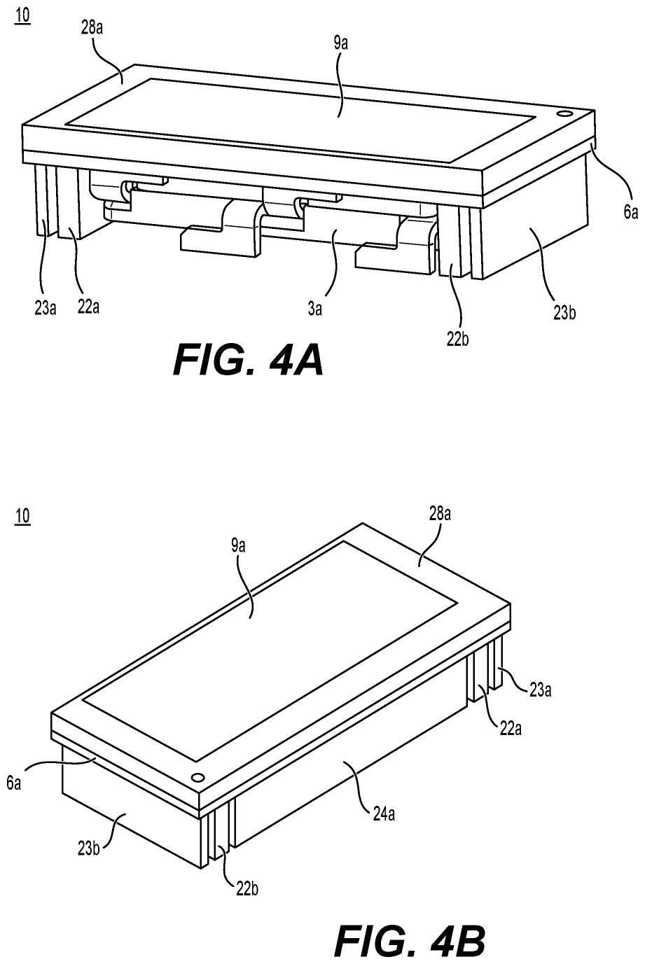

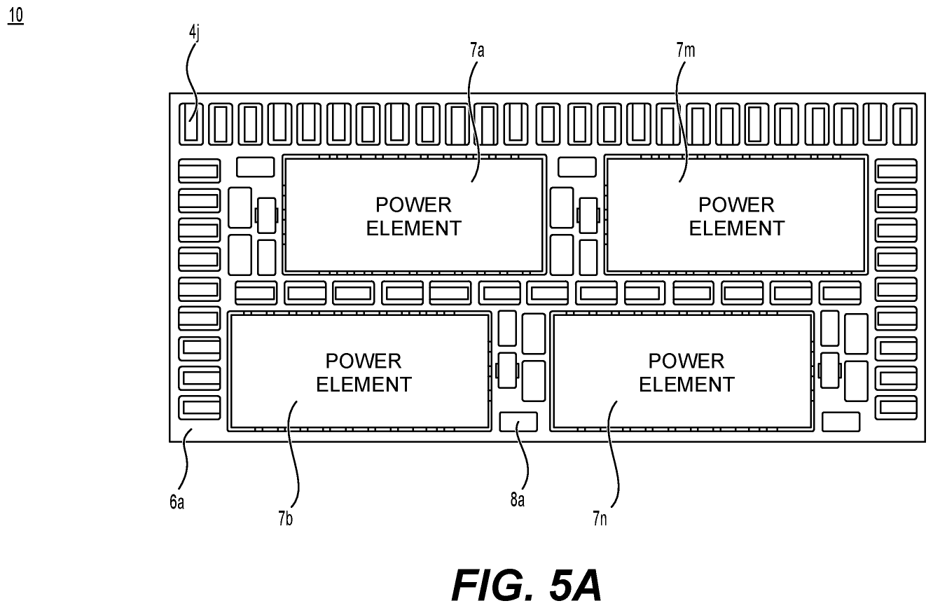

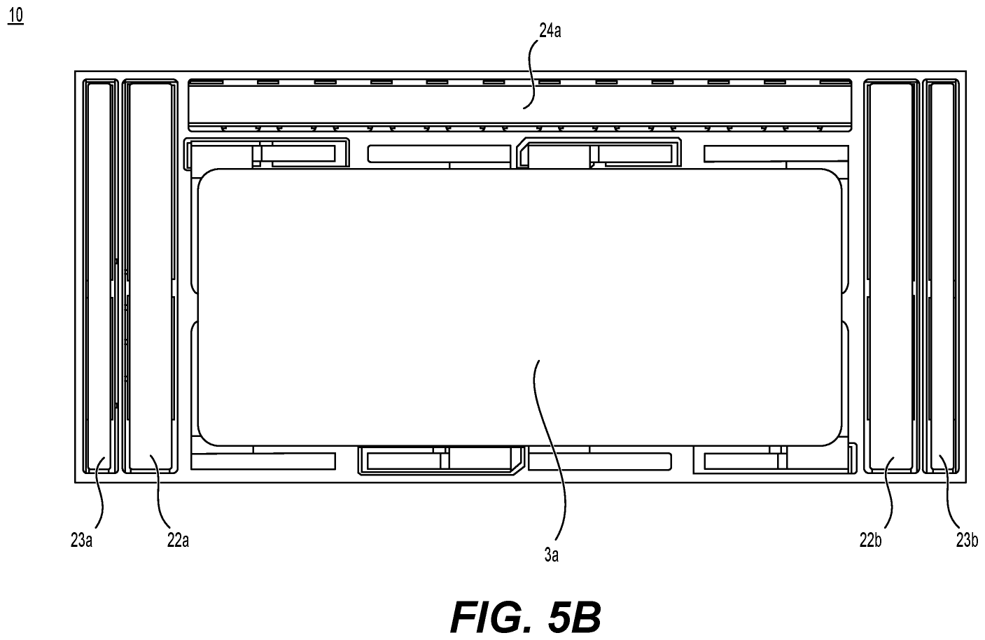

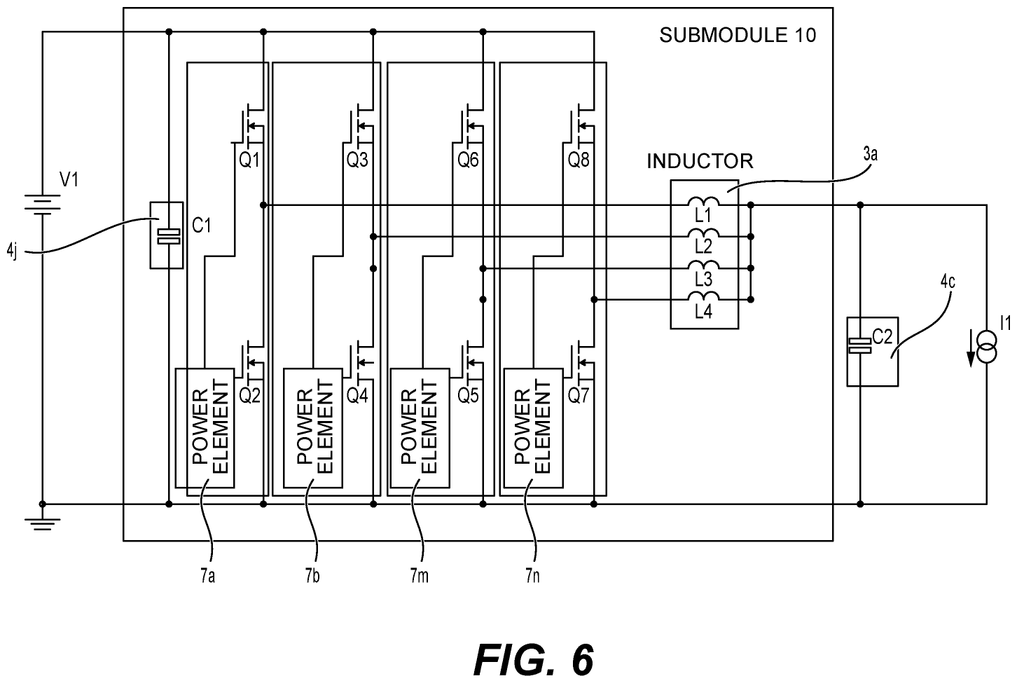

FIGS. 1-3 show a power supply module 1 that includes a common substrate (referred to as the first substrate 2 below) and submodules mounted on the first substrate 2. FIGS. 4A-5B show an example of a submodule 10 that can be used with the power supply module 1. FIG. 6 shows a circuit diagram including the components of the submodule 10.

As shown in FIGS. 1-3, the power supply module 1 can include six submodules attached to the first substrate 2. Alternatively, any number of submodules can be used. Each submodule can include a second substrate and associated electronics components. The power supply module 1, depending on the design of the power supply module, can include active devices such as power elements mounted on the first substrate 2 and can include passive devices such as resistors, capacitors, and inductors mounted on the first substrate 2. The power elements can include, for example, power transistors, drivers for power transistors, etc. For example, the power supply module 1 can include one or more control integrated circuits (ICs). Any suitable control ICs can be used, and the number, the type, and the arrangement of IC(s) will depend on the design of the power supply module.

Each submodule, depending on the design of the submodule, can include active devices such as power elements and can include passive devices such as resistors, capacitors, and inductors. The power elements can include, for example, power transistors, drivers for power transistors, etc. Each submodule can also include a heat sink. In FIGS. 1-3, each submodule is the same or similar, but it is also possible to provide submodules with different arrangements and/or functions.

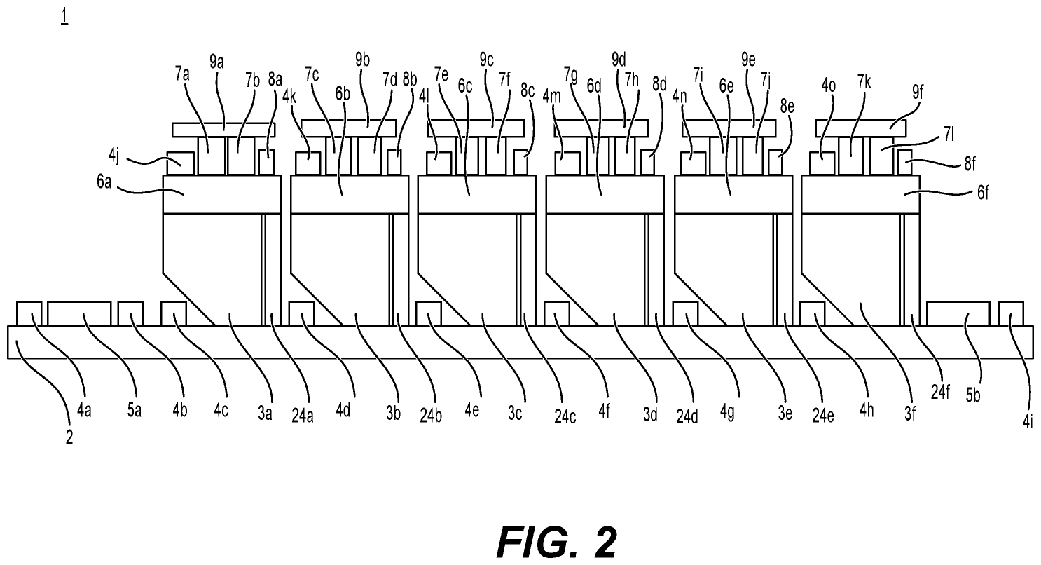

As shown in FIGS. 1-3, the power supply module 1 can include inductors 3a, 3b, 3c, 3d, 3e, and 3f, capacitors 4a, 4b, 4c, 4d, 4e, 4f, 4g, 4h, 4i, and 4j, control ICs 5a and 5b, ground terminals 22a and 22b, voltage input terminals 23a and 23b, signal transmission substrates 24a, 24b, 24c, 24d, 24e, and 24f mounted on a principal surface of the first substrate 2. As shown in FIG. 2, electronic components, such as capacitors 4a, 4b, 4c, 4d, 4e, 4f, 4g, and 4h, can be located underneath a portion of a respective inductor 3a, 3b, 3c, 3d, 3e, and 3f. The ground terminals 22a and 22b can extend from opposite ends of the respective second substrates 6a, 6b, 6c, 6d, 6e, and 6f. The voltage input terminals 23a and 23b can extend from opposite ends of the respective second substrates 6a, 6b, 6c, 6d, 6e, and 6f. The ground terminals 22a and 22b can be inside of the voltage input terminals 23a and 23b.

As shown in FIG. 2, the power supply module 1 can include:
1. a first submodule including a second substrate 6a, including a signal transmission substrate 24a, ground terminals 22a, 22b, and voltage input terminals 23a, 23b extending between the second substrate 6a and the first substrate 2, including a capacitor 4j, power elements 7a and 7b, and a resistor 8a on a principal surface of the second substrate 6a, and including a heat sink 9a above the power elements 7a and 7b;
2. a second submodule including a second substrate 6b, including a signal transmission substrate 24b, ground terminals (not labeled), and voltage input terminals (not labeled) extending between the second substrate 6b and the first substrate 2, including a capacitor 4k, power elements 7c and 7d, and a resistor 8b on a principal surface of second substrate 6b, and including a heat sink 9b above the power elements 7c and 7d;
3. a third submodule including a second substrate 6c, including a signal transmission substrate 24c, ground terminals (not labeled), and voltage input terminals (not labeled) extending between the second substrate 6c and the first substrate 2, including a capacitor 41, power element 7e and 7f, and a resistor 8c on a principal surface of the second substrate 6c, and including a heat sink 9c above the power elements 7e and 7f;
4. a fourth submodule including a second substrate 6d, including a signal transmission substrate 24d, ground terminals (not labeled), and voltage input terminals (not labeled) extending between the second substrate 6d and the first substrate 2, including a capacitor 4m, power elements 7g and 7h, and a resistor 8d located on a principal surface of the second substrate 6d, and including a heat sink 9d above the power elements 7g and 7h;
5. a fifth submodule including a second substrate 6e, including a signal transmission substrate 24e, ground terminals (not labeled), and voltage input terminals (not labeled) extending between the second substrate 6e and the first substrate 2, including a capacitor 4n, power elements 7i and 7j, and a resistor 8e located on a principal surface of the second substrate 6e, and including a heat sink 9e above the power elements 7i and 7j; and
6. a sixth submodule including a second substrate 6f, including a signal transmission substrate 24f, ground terminals (not labeled), and voltage input terminals (not labeled) extending between the second substrate 6f and the first substrate 2, including a capacitor 4o, power elements 7k and 7l, and a resistor 8f are located on a principal surface of the second substrate 6f, and including heat sink 9f above the power elements 7k and 7l.

The power supply module 1 allows the shape of the first substrate 2 to be changed according to the number and location of each submodule to provide miniaturization and/or high integration. For example, if the six submodules are located side by side such that the front and rear sides of each submodule shown in FIG. 4A and FIG. 4B are generally parallel to the Y-axis direction of FIG. 1 as shown in FIG. 1, then the first substrate 2 can have a rectangular shape with the sides parallel to the Y-axis as the long sides. In other words, the length of the short side can be less than twice the length of the long side of the submodule.

Heat sinks 9a-9f can be used to dissipate heat in the power supply module, but other structures and/or materials can also be used to dissipate heat. In some applications, a heatsink might not be needed.

As shown in FIGS. 1-3, the second substrate 6a of the first submodule can be molded by resin 28a to cover electronic components on the principal surface of the second substrate 6a that is not opposed to the first substrate 2, the second substrate 6b of the second submodule can be molded by resin 28b to cover electronic components on the principal surface of the second substrate 6b that is not opposed to the first substrate 2, the second substrate 6c of the third submodule can be molded by resin 28c to cover electronic components on the principal surface of the second substrate 6c that is not opposed to the first substrate 2, the second substrate 6d of the fourth submodule can be molded by resin 28d to cover electronic components on the principal surface of the second substrate 6d that is not opposed to the first substrate 2, the second substrate 6e of the fifth submodule can be molded by resin 28e to cover electronic components the principal surface of the second substrate 6e that is not opposed to the first substrate 2 and the second substrate 6f of the sixth submodule can be molded by resin 28f to cover electronic components on the principal surface of the second substrate 6f that is not opposed to the first substrate 2.

FIGS. 4A-5B show an example of a submodule 10 that can be used with the power supply module 1.

As shown in FIGS. 4A, 4B, and 5A, the submodule 10 can include power elements 7a, 7b, 7m, 7n, a resistor 8a, and a capacitor 4j on a top surface of the second substrate 6a. As shown in FIG. 5B, the submodule 10 can include an inductor 3a, voltage input terminals 23a, 23b, ground terminals 22a, 22b, and a signal transmission substrate 24a underneath the bottom surface of the second substrate 6a. These electronic components can be electrically connected to each other to provide various function of the submodule 10. A power supply module 1 can be constructed by mounting at least one submodule 10 on a first substrate 2.

As shown in FIGS. 1, 2, 4A, and 4B, the inductor 3a can be located on the principal surface of the first substrate 2. The inductors 3a-3f can be physically connected to the first substrate 2 and the respective second substrate 6a-6f through a conductive joining material such as solder, for example.

As shown in FIGS. 1, 2, 4A, and 4B, for each submodule, the ground terminals 22a and 22b, the voltage input terminals 23a and 23b can be located outside the respective inductors 3a-3f along the long side direction of the principal surface of the first substrate 2. As shown in FIGS. 1, 2, 4A, and 4B, for each submodule, the signal transmission substrates 24a-24f can be located outside the inductor 3a along the short side direction of the principal surface of the first substrate 2. For each submodule, the ground terminals 22a and 22b, the voltage input terminals 23a and 23b, and the signal transmission substrates 24a-24f can be physically connected to the first substrate 2 and the respective second substrate 6a-6f. For each submodule, the ground terminals 22a and 22b, the voltage input terminals 23a and 23b, and the signal transmission substrates 24a-24f can support the respective second substrate 6a-6f. For each submodule, the ground terminals 22a and 22b, which are located on the principal surface of the first substrate 2, and the signal transmission substrates 24a-24f can transmit signals and/or power.

As shown in FIGS. 4A-5B, the inductor 3a, the ground terminals 22a and 22b, the voltage input terminals 23a and 23b, and the signal transmission substrate 24a can be located on the lower surface of the second substrate 6a. The inductor 3a, the ground terminals 22a and 22b, the voltage input terminals 23a and 23b, and the signal transmission substrate 24a are specific examples of electronic components located on the lower surface of the second substrate 6a, but other electronic components can be used instead or in addition to these electronic components.

As shown in FIGS. 1-4B, the second substrate 6a-6f can be located so that the second substrate 6a-6f covers respective top surfaces of the inductor 3a-3f, the ground terminals 22a and 22b, the voltage input terminals 23a and 23b, and the signal transmission substrate 24a-24f. In other words, the second substrate 6a-6f can be located on a surface opposing to the respective surfaces of the inductor 3a-3f, the ground terminals 22a and 22b, the voltage input terminals 23a and 23b, and the signal transmission substrate 24a-24f that are in contact with the first substrate 2.

As shown in FIGS. 5A, the power elements 7a, 7b, 7m, and 7n, the capacitor 4j and the resistor 8a can be on the principal surface of the second substrate 6a that is not opposed to the first substrate 2. Any number and any arrangement of passive and active devices can be used. For example, any number and any arrangement of capacitors, resistors, and power elements can be included in the submodule.

As shown in FIGS. 4A-6, the electronic components of the submodule 10 can be electrically connected via the second substrate 6a.

By adopting the structure of the power supply module 1 as described above, it is possible to provide a power supply module with a structure that allow more electronic components to be mounted and that allow more flexibility in design of functions, size, performance, etc.

By using the second substrate 6a-6f located in the direction perpendicular or substantially perpendicular within manufacturing and/or measurement tolerances to the principal surface of the first substrate 2, electronic components can be located, not only on the principal plane of the first substrate 2, but also on the second substrate 6a-6f, which allows more electronic components to be used than if only the first substrate were present.

Moreover, by using more than one second substrate, adjustments, such as reducing the area of each second substrate 6a-6f, can be made. As a result, it is possible to ensure the strength of the second substrate 6a-6f.

It is also possible to change the number, the shape, and the size of the electronic components in the power supply module by changing the shape and the size of the first substrate 2 and the second substrate(s) 6a-6f.

The number and the type of electronic components of the submodule 10 can be changed. Thus, a power supply module with various functions can be provided.

In the power supply module 1, more than one submodule 10 can be located on the principal surface of the first substrate 2. For example, by increasing the number of submodules 10, greater power output can be achieved. When multiple submodules 10 are used, the submodules 10 can be electrically connected to each other.

FIG. 6 shows a possible circuit diagram including the components in the submodule 10 and on the first substrate 2 of the power supply module 1. The capacitor 4j (C1) of the submodule 10 can be connected in parallel with a power supply V1. Power elements 7a, 7b, 7m, and 7n can be used to drive switches Q1-Q8 in the submodule 10. Series-connected switches Q1 and Q2 can be connected in parallel with the power supply V1, series-connected switches Q3 and Q4 can be connected in parallel with the power supply V1, series-connected switches Q5 and Q6 can be connected in parallel with the power supply V1, and series-connected switches Q7 and Q8 can be connected in parallel with the power supply V1. Series-connected switches Q1 and Q2, series-connected switches Q3 and Q4, series-connected switches Q5 and Q6, and series-connected switches Q7 and Q8 can be connected in parallel with each other. A node between series-connected switches Q1 and Q2 can be connected to a sub-inductor L1 of the inductor 3a, a node between series-connected switches Q3 and Q4 can be connected to a sub-inductor L2 of the inductor 3a, a node between series-connected switches Q5 and Q6 can be connected to a sub-inductor L3 of the inductor 3a, and a node between series-connected switches Q7 and Q8 can be connected to a sub-inductor L4 of the inductor 3a. The inductor 3a of the submodule 10 can be connected the capacitor 4c (C2) on the first substrate 2 of the power supply module 1. The capacitor 4c (C2) can be connected in parallel with a current source 11.

### Second Preferred Embodiment

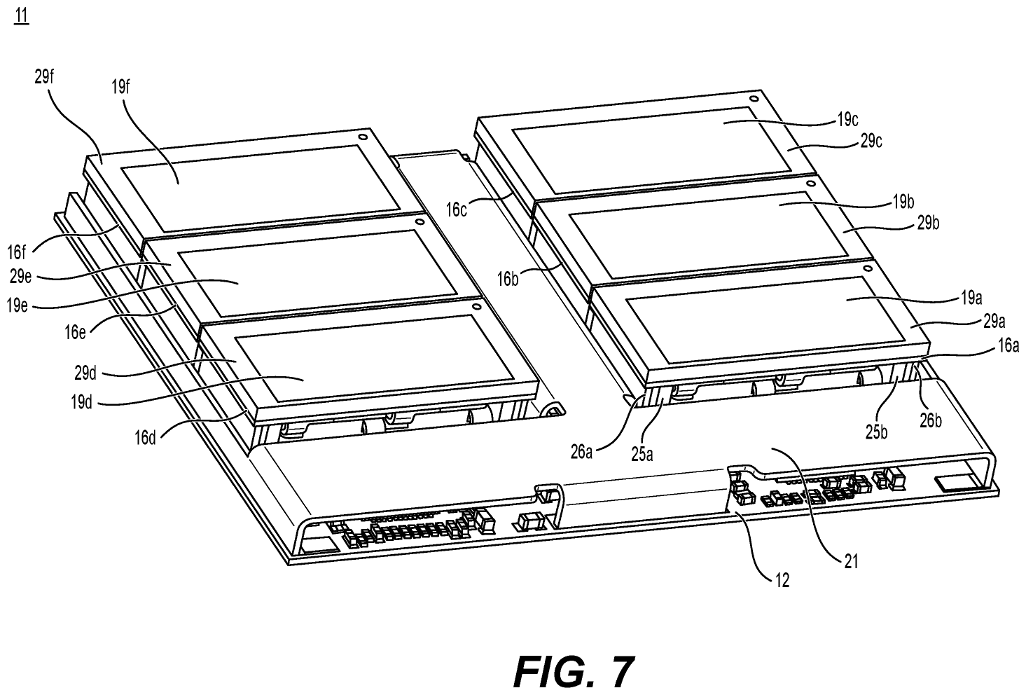

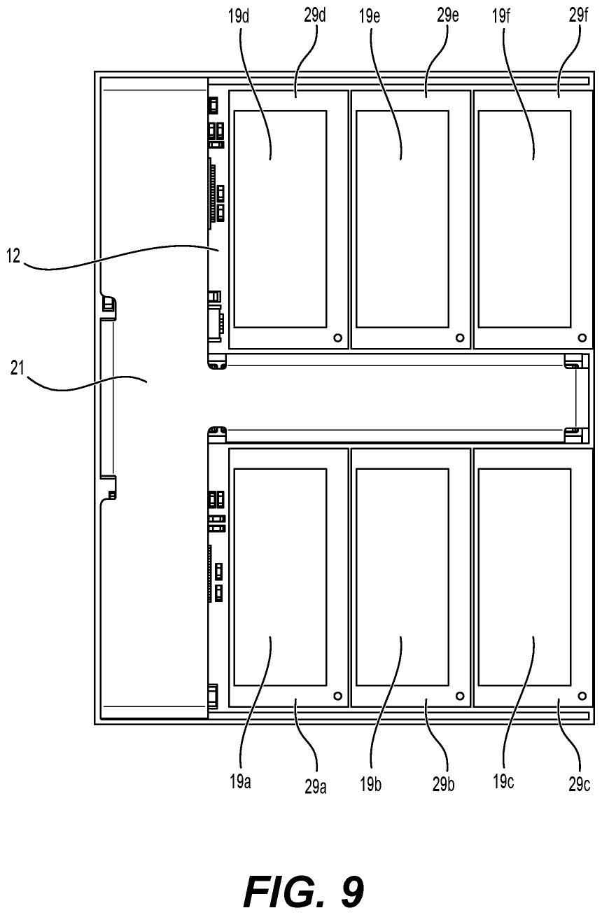

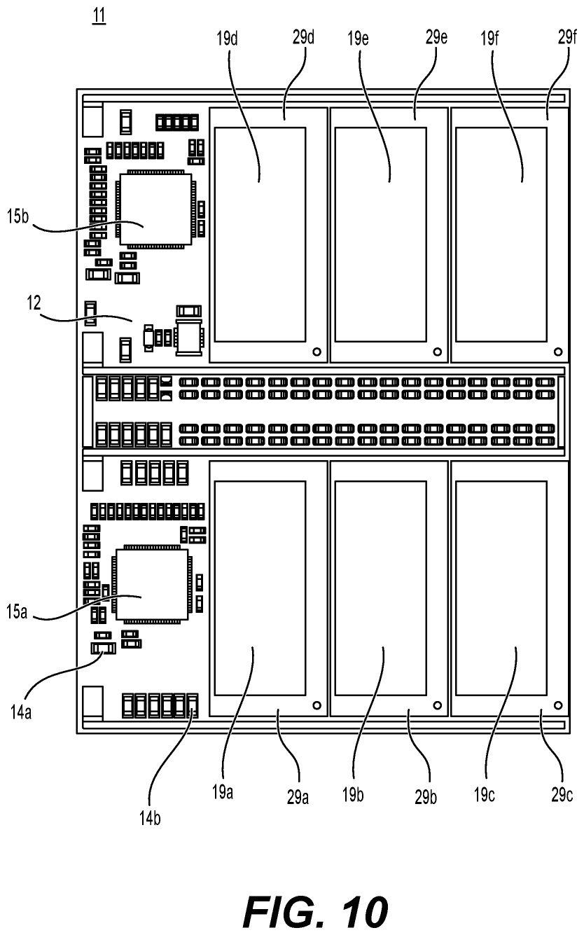

FIGS. 7-13 shows a power supply module 11 according to a second preferred embodiment of the present invention. The power supply module 11 of the second preferred embodiment and the power supply module 1 are similar, except that the submodules of the power supply module 11 have a different arrangement compared to the submodules of the power supply module 1.

As shown in FIGS. 7-9, the power supply module 11 can include six submodules attached to the first substrate 12. Alternatively, any number of submodules can be used. Each submodule can include a second substrate and associated electronics components. The power supply module 11, depending on the design of the power supply module, can include active devices such as power elements mounted on the first substrate 12 and can include passive devices such as resistors, capacitors, and inductors mounted on the first substrate 12. For example, the power supply module 11 can include one or more control integrated circuits (ICs). Any suitable control ICs can be used, and the number, the type, and the arrangement of IC(s) will depend on the design of the power supply module.

Each submodule, depending on the design of the submodule, can include active devices such as power elements and can include passive devices such as resistors, capacitors, and inductors. Each submodule can also include a heat sink. In FIGS. 7-9, each submodule is the same or similar, but it is also possible to provide submodules with different arrangements and/or functions.

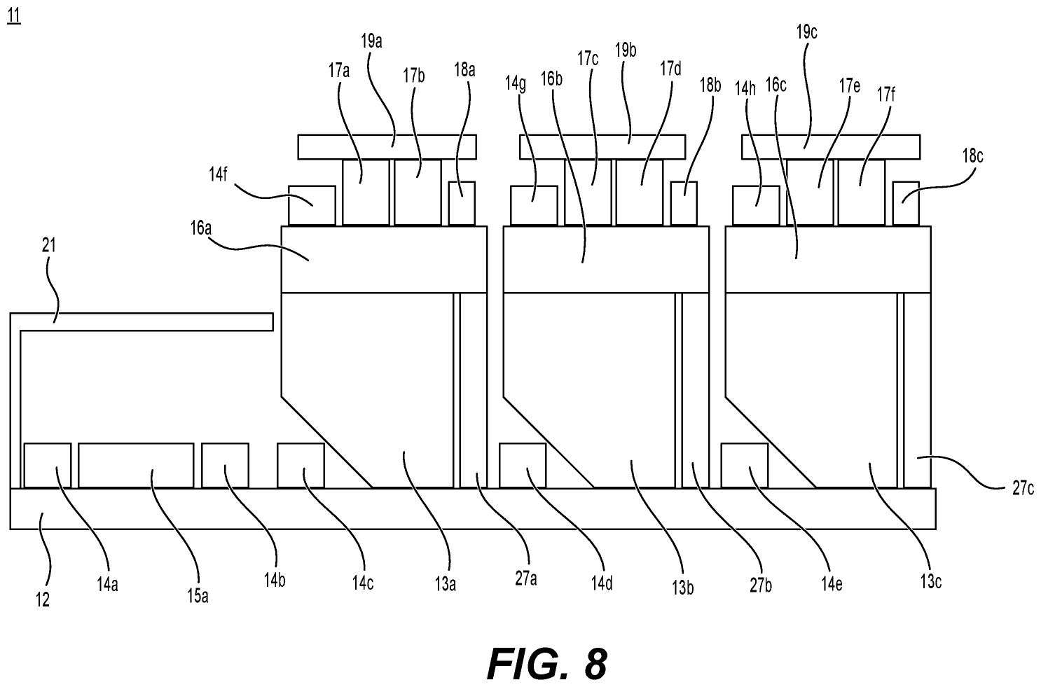

As shown in FIGS. 7-10, the power supply module 11 can include inductors 13a, 13b, 13c (only three inductors are shown in FIG. 8), capacitors 14a, 14b, 14c, 14d, 14e, 14f, 14g, and 14h, control ICs 15a and 15b underneath metal plate 21, ground terminals 22a and 22b, voltage input terminals 23a and 23b, signal transmission substrates 24a, 24b, 24c, 24d, 24e, and 24f mounted on a principal surface of the first substrate 2. As shown in FIG. 8, electronic components, such as capacitors 14c, 14d, and 14e, can be located underneath a portion of a respective inductor 13a, 13b, and 13c. The ground terminals 25a and 25b can extend from opposite ends of the respective second substrates 16a, 16b, 16c, 16d, 16e, and 16f. The voltage input terminals 26a and 26b can extend from opposite ends of the respective second substrates 16a, 16b, 16c, 16d, 16e, and 16f. The ground terminals 25a and 25b can be inside of the voltage input terminals 26a and 26b.

FIG. 8 only shows three submodules, but three additional submodules arranged adjacent to the three submodules shown in FIG. 8 can also be included as shown in FIGS. 7, 9, and 10. As shown in FIG. 8, the power supply module 11 can include:
1. a first submodule including a second substrate 16a, including a signal transmission substrate 27a, ground terminals 25a, 25b, and voltage input terminals 26a, 25b extending between the second substrate 16a and the first substrate 12, including a capacitor 14f, power elements 17a and 17b, and a resistor 18a on a principal surface of the second substrate 16a, and including a heat sink 19a above the power elements 17a and 17b;
2. a second submodule including a second substrate 16b, including a signal transmission substrate 27b, ground terminals (not labeled), and voltage input terminals (not labeled) extending between the second substrate 16b and the first substrate 12, including a capacitor 14g, power elements 17c and 17d, and a resistor 18b on a principal surface of second substrate 16b, and including a heat sink 19b above the power elements 17c and 17d; and
3. a third submodule including a second substrate 16c, including a signal transmission substrate 27c, ground terminals (not labeled), and voltage input terminals (not labeled) extending between the second substrate 16c and the first substrate 12, including a capacitor 14h, power element 17e and 17f, and a resistor 18c on a principal surface of the second substrate 16c, and including a heat sink 19c above the power elements 17e and 17f.
   The three other submodules arranged in a parallel line adjacent to the first-third submodules can include a similar arrangement of components as the first-third submodules.

As shown in FIGS. 7-9, the power supply module 11 can include be molded by a metal plate 21 that can cover the capacitor 14a and 14b, the control ICs 15a and 15b that are located on the principal surface of the first substrate 12.

Heat sinks 19a-19f can be used to dissipate heat in the power supply module, but other structures and/or materials can also be used to dissipate heat. In some applications, a heatsink might not be needed.

As shown in FIGS. 7-10, the second substrate 16a of the first submodule can be molded by resin 29a to cover electronic components on the principal surface of the second substrate 16a that is not opposed to the first substrate 12, the second substrate 16b of the second submodule can be molded by resin 29b to cover electronic components on the principal surface of the second substrate 16b that is not opposed to the first substrate 12, the second substrate 16c of the third submodule can be molded by resin 29c to cover electronic components on the principal surface of the second substrate 16c that is not opposed to the first substrate 12, the second substrate 16d of the fourth submodule can be molded by resin 29d to cover electronic components on the principal surface of the second substrate 16d that is not opposed to the first substrate 12, the second substrate 16e of the fifth submodule can be molded by resin 29e to cover electronic components the principal surface of the second substrate 16e that is not opposed to the first substrate 12 and the second substrate 16f of the sixth submodule can be molded by resin 29f to cover electronic components on the principal surface of the second substrate 16f that is not opposed to the first substrate 12.

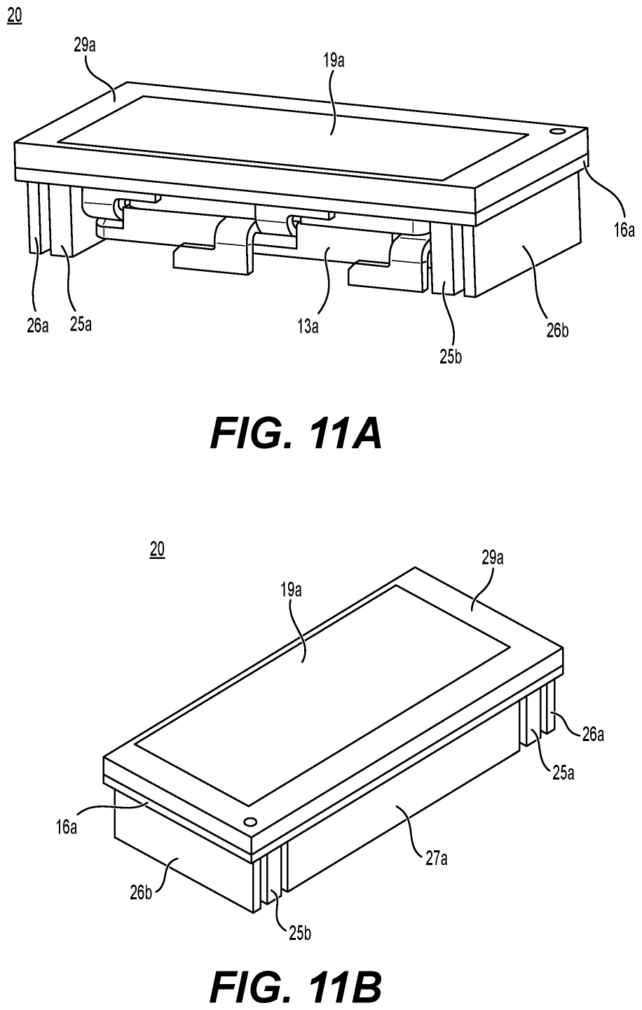

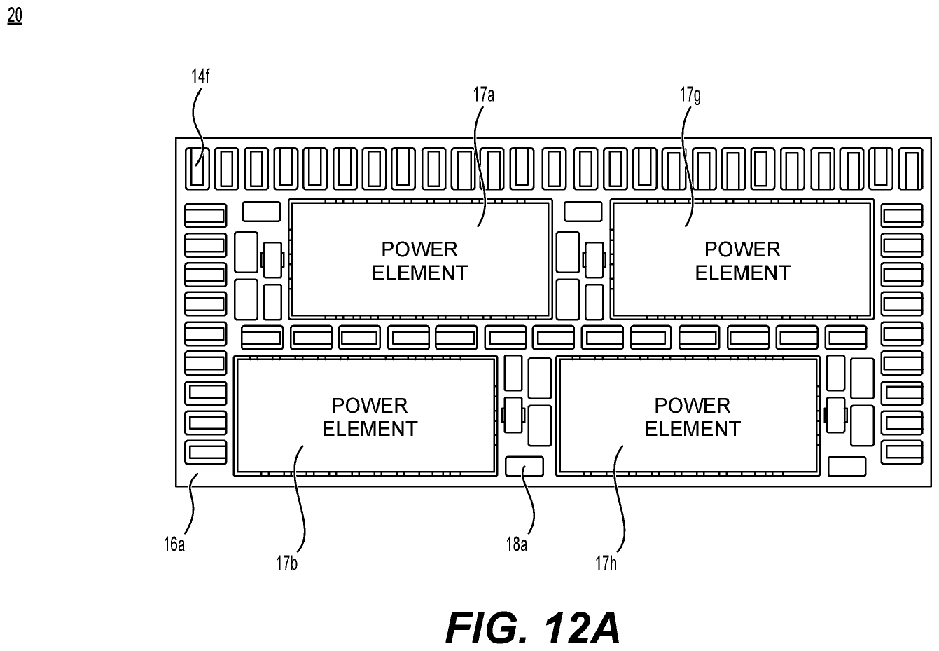

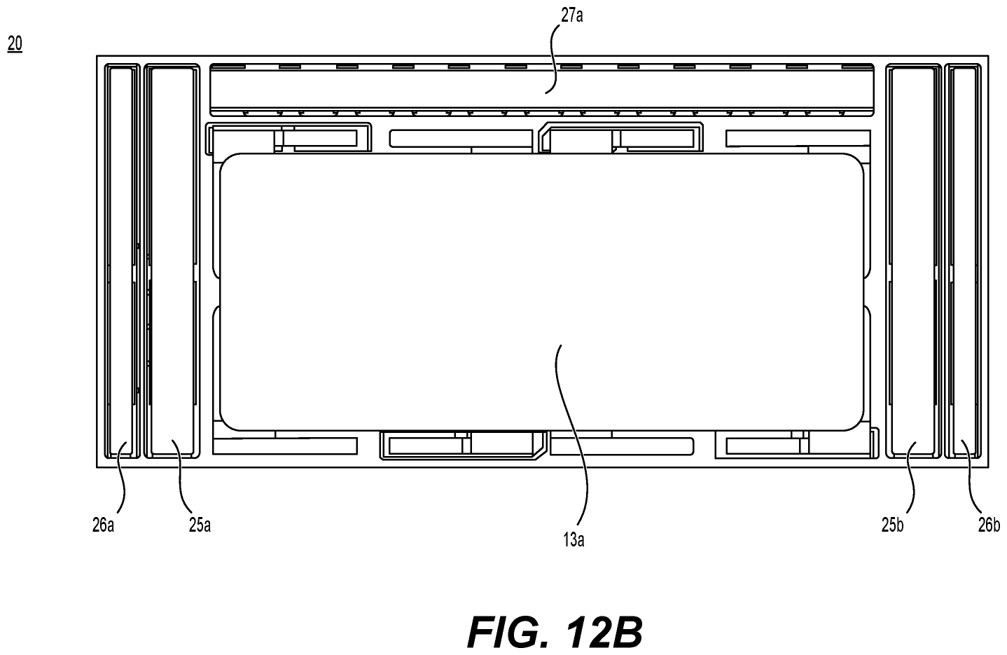

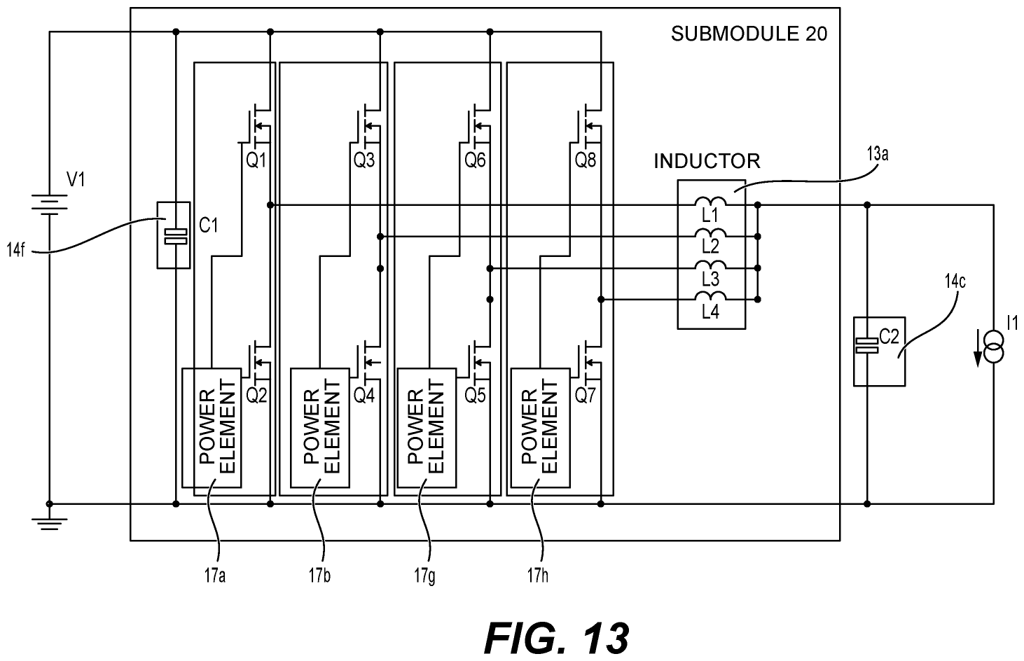

FIGS. 11A-12B show an example of a submodule 20 that can be used with the power supply module 11.

As shown in FIGS. 11A, 11B, and 12A, the submodule 20 can include power elements 17a, 17b, 17g, 17h, a resistor 18a, and a capacitor 14f on a top surface of the second substrate 16a. As shown in FIG. 12B, the submodule 20 can include an inductor 13a, voltage input terminals 26a, 26b, ground terminals 25a, 25b, and a signal transmission substrate 27a underneath the bottom surface of the second substrate 16a. These electronic components can be electrically connected to each other to provide various function of the submodule 20. A power supply module 11 can be constructed by mounting at least one submodule 10 on a first substrate 12.

As shown in FIGS. 7, 8, 11A, and 11B, the inductor 13a can be located on the principal surface of the first substrate 12. The inductors 13a-13c can be physically connected to the first substrate 12 and the respective second substrate 16a-16f through a conductive joining material such as solder, for example.

As shown in FIGS. 7, 8, 11A, and 11B, for each submodule, the ground terminals 25a and 25b, the voltage input terminals 26a and 26b can be located outside the respective inductors 13a-13c along the long side direction of the principal surface of the first substrate 12. As shown in FIGS. 7, 8, 11A, and 11B, for each submodule, the signal transmission substrates 27a-27c can be located outside the inductor 13a along the short side direction of the principal surface of the first substrate 12. For each submodule, the ground terminals 25a and 25b, the voltage input terminals 26a and 26b, and the signal transmission substrates 27a-27c can be physically connected to the first substrate 12 and the respective second substrate 16a-16f. For each submodule, the ground terminals 25a and 25b, the voltage input terminals 26a and 26b, and the signal transmission substrates 27a-27c can support the respective second substrate 16a-16f. For each submodule, the ground terminals 25a and 25b, which are located on the principal surface of the first substrate 12, and the signal transmission substrates 27a-27c can transmit signals and/or power.

As shown in FIGS. 4A-5B, the inductor 13a, the ground terminals 25a and 25b, the voltage input terminals 26a and 26b, and the signal transmission substrate 27a can be located on the lower surface of the second substrate 16a. The inductor 13a, the ground terminals 25a and 25b, the voltage input terminals 26a and 26b, and the signal transmission substrate 27a are specific examples of electronic components located on the lower surface of the second substrate 16a, but other electronic components can be used instead or in addition to these electronic components.

As shown in FIGS. 7-11B, the second substrate 16a-16f can be located so that the second substrate 16a-16f covers respective top surfaces of the inductor 13a-13c, the ground terminals 25a and 25b, the voltage input terminals 26a and 26b, and the signal transmission substrate 27a-27c. In other words, the second substrate 16a-16f can be located on a surface opposing to the respective surfaces of the inductor 13a-13c, the ground terminals 25a and 25b, the voltage input terminals 26a and 26b, and the signal transmission substrate 27a-27c that are in contact with the first substrate 12.

As shown in FIGS. 12A, the power elements 17a, 17b, 17g, and 17h, the capacitor 14f and the resistor 18a can be on the principal surface of the second substrate 16a that is not opposed to the first substrate 12. Any number and any arrangement of passive and active devices can be used. For example, any number and any arrangement of capacitors, resistors, and power elements can be included in the submodule.

As shown in FIGS. 11A-13, the electronic components of the submodule 10 can be electrically connected via the second substrate 16a.

By adopting the structure of the power supply module 11 as described above, it is possible to provide a power supply module with a structure that allow more electronic components to be mounted and that allow more flexibility in design of functions, size, performance, etc.

By using the second substrate 16a-26f located in the direction perpendicular or substantially perpendicular within manufacturing and/or measurement tolerances to the principal surface of the first substrate 12, electronic components can be located, not only on the principal plane of the first substrate 12, but also on the second substrate 16a-16f, which allows more electronic components to be used than if only the first substrate were present.

Moreover, by using more than one second substrate, adjustments, such as reducing the area of each second substrate 16a-16f, can be made. As a result, it is possible to ensure the strength of the second substrate 16a-16f.

It is also possible to change the number, the shape, and the size of the electronic components in the power supply module by changing the shape and the size of the first substrate 12 and the second substrate(s) 16a-16f.

The number and the type of electronic components of the submodule 20 can be changed. Thus, a power supply module with various functions can be provided.

In the power supply module 11, more than one submodule 20 can be located on the principal surface of the first substrate 12. For example, by increasing the number of submodules 20, greater power output can be achieved. When multiple submodules 20 are used, the submodules 20 can be electrically connected to each other.

When the power supply module 11 is viewed from the top, it is molded by the metal plate 21 to cover the first substrate 12, the second substrate 16a-16f that do not overlap. This makes it possible to secure the strength of the first substrate 12.

FIG. 13 shows a possible circuit diagram including the components in the submodule 20 and on the first substrate 12 of the power supply module 11. The capacitor 14f (C1) of the submodule 20 can be connected in parallel with a power supply V1. Power elements 17a, 17b, 17g, and 17h can be used to drive switches Q1-Q8 in the submodule 20. Series-connected switches Q1 and Q2 can be connected in parallel with the power supply V1, series-connected switches Q3 and Q4 can be connected in parallel with the power supply V1, series-connected switches Q5 and Q6 can be connected in parallel with the power supply V1, and series-connected switches Q7 and Q8 can be connected in parallel with the power supply V1. Series-connected switches Q1 and Q2, series-connected switches Q3 and Q4, series-connected switches Q5 and Q6, and series-connected switches Q7 and Q8 can be connected in parallel with each other. A node between series-connected switches Q1 and Q2 can be connected to a sub-inductor L1 of the inductor 3a, a node between series-connected switches Q3 and Q4 can be connected to a sub-inductor L2 of the inductor 3a, a node between series-connected switches Q5 and Q6 can be connected to a sub-inductor L3 of the inductor 3a, and a node between series-connected switches Q7 and Q8 can be connected to a sub-inductor L4 of the inductor 3a. The inductor 3a of the submodule s0 can be connected the capacitor 14c (C2) on the first substrate 2 of the power supply module 1. The capacitor 14c (C2) can be connected in parallel with a current source I1.

It should be understood that the foregoing description is only illustrative of the present invention. Various alternatives and modifications can be devised by those skilled in the art without departing from the present invention. Accordingly, the present invention is intended to embrace all such alternatives, modifications, and variances that fall within the scope of the appended claims.

1. A power supply module comprising:
a first substrate;
a control IC, a capacitor, a first electronic component, a second electronic component, a third electronic component, and a fourth electronic component on a principal surface of the first substrate; and
a submodule including:
a second substrate above the first electronic component, the second electronic component, the third electronic component, and the fourth electronic component;
a fifth electronic component, a sixth electronic component, and a seventh electronic component on a principal surface of the second substrate; and
a resin covering an upper portion of the submodule.

2. The module of claim 1, wherein the first electronic component is an inductor.

3. The module of claim 1, wherein the second electronic component is a ground terminal.

4. The module of claim 1, wherein the third electronic component is a voltage input terminal.

5. The module of claim 1, wherein the fourth electronic component is a signal transmission substrate.

6. The module of claim 1, wherein the fifth electronic component is a power element.

7. The module of claim 6, further comprising a heat sink above the power element.

8. The module of claim 1, wherein the sixth electronic component is a capacitor.

9. The module of claim 1, wherein the seventh electronic component is a resistor.

10. The module of claim 1, further comprising one or more additional submodules, and the submodule and the one or more additional submodules are electrically connected to each other.

11. A power supply module comprising:
a first substrate;
a control IC, a capacitor, a first electronic component, a second electronic component, a third electronic component, and a fourth electronic component on a principal surface of the first substrate;
a submodule including:
a second substrate above the first electronic component, the second electronic component, the third electronic component, and the fourth electronic component;
a fifth electronic component, a sixth electronic component, and a seventh electronic component on a principal surface of the second substrate; and
a resin covering an upper portion of the first submodule;
a metal plate on a principal surface of the first substrate where the first submodule is not located.

12. The module of claim 11, wherein the first electronic component is an inductor.

13. The module of claim 11, wherein the second electronic component is a ground terminal.

14. The module of claim 11, wherein the third electronic component is a voltage input terminal.

15. The module of claim 11, wherein the fourth electronic component is a signal transmission substrate.

16. The module of claim 11, wherein the fifth electronic component is a power element.

17. The module of claim 16, further comprising a heat sink above the power element.

18. The module of claim 11, wherein the sixth electronic component is a capacitor.

19. The module of claim 11, wherein the seventh electronic component is a resistor.

20. The module of claim 11, further comprising one or more additional submodules, and the submodule and the one or more additional submodules are electrically connected to each other.

21. A power supply module comprising:
a first substrate;
first and second submodules, each of the first and second submodules includes:
a second substrate;
a signal transmission substrate connected between the first substrate and the second substrate;
a power element on a first principal surface of the second substrate opposite to the first substrate; and
an inductor on a second principal surface of the second substrate facing the first substrate and electrically connected with the power element.

22. The module of claim 21, further comprising a metal plate on a principal surface of the first substrate where the first and second submodules are not located.

23. The module of claim 22, further comprising third and fourth submodules; wherein
the first and the second submodules are arranged in a first line; and
the third and the fourth submodules are arranged in a second line adjacent to the first line.

24. The module of claim 21, further comprising a control IC on the first substrate.

25. The module of claim 21, further comprising first and second electronic components mounted to the first substrate; wherein
the first electronic component is underneath a portion of the inductor of the first submodule; and
the second electronic components is underneath a portion of the second submodule.

26. The module of claim 21, wherein each of the first and the second submodules includes a resin covering an upper portion of thereof.

27. The module of claim 21, wherein
each of the first and the second submodules includes first and second voltage input terminals;
the first voltage input terminal is connected between the first substrate and a first end of the second substrate; and
the second voltage input terminal is connected between the first substrate and a second end of the second substrate opposite to the first end of the second substrate.

28. The module of claim 27, wherein
each of the first and the second submodules includes first and second ground terminals;
the first ground terminal is connected between the first substrate and the first end of the second substrate;
the second ground terminal is connected between the first substrate and the second end of the second substrate; and
the first and the second ground terminals are located inside the first and the second voltage input terminals.

29. The module of claim 21, wherein each of the first and the second submodules includes a heat sink above the power element.

30. The module of claim 21, wherein the first and the second submodules are electrically connected.
